(19) United States
(12) Patent Application Publication
(10) Pub. No.: US 2026/0293495 A1
(43) Pub. Date: Sep. 24, 2026

(54) Display Device And Electronic Device Including The Same

(71) Applicant: Samsung Display Co., Ltd., Yongin-si (KR)

(72) Inventors: Oh June Kwon, Yongin-si (KR); Woo Yong Sung, Yongin-si (KR); Seung Yong Song, Yongin-si (KR); Kyu Jin Cho, Yongin-si (KR)

(73) Assignee: Samsung Display Co., Ltd., Yongin-si (KR)

(21) Appl. No.: 19/449,746

(22) Filed: Jan. 15, 2026

(30) Foreign Application Priority Data
Mar. 24, 2025 (KR) 10-2025-0037126

(51) Int. Cl. H10K 59/80; H10K 59/131

(52) U.S. Cl. CPC H10K 59/873; H10K 59/131

(57) ABSTRACT

A display device may include: an inorganic encapsulation area surrounding a through-hole; a wiring area surrounding the inorganic encapsulation area; and a display area surrounding the wiring area. The inorganic encapsulation area includes: a first organic film including a first sub-organic film having a first inclined surface and a second sub-organic film having a second inclined surface facing the first opposing inclined surface; a first groove between the first sub-organic film and the second sub-organic film; and a protrusion including at least a portion of the first organic film, wherein the protrusion is raised between the first sub-organic film and the second sub-organic film. An electronic device may include the display device.

### CROSS-REFERENCE TO RELATED APPLICATION

This application claims priority under 35 U.S.C. §119 to Korean Patent Application No. 10-2025-0037126 filed on Mar. 24, 2025, in the Korean Intellectual Property Office, the contents of which are incorporated by reference herein in their entirety.

### TECHNICAL FIELD

The present disclosure relates to a display device and an electronic device including the same.

### BACKGROUND

As the information society advances, demand for display devices for displaying images has been increasing in various forms. For example, display devices are being applied to various electronic devices such as smartphones, digital cameras, notebook computers, navigation systems, and smart televisions.

Display devices include light-receiving display devices such as liquid crystal display devices, field-emission display devices, and light-emitting display devices. Light-emitting display devices include, for example, organic light-emitting display devices having organic light-emitting elements, inorganic light-emitting display devices having inorganic light-emitting elements such as inorganic semiconductors, and micro-light-emitting display devices having micro-light-emitting elements.

### SUMMARY

One objective of the present disclosure is to provide a display device with improved durability.

The objectives of the present disclosure are not limited to those mentioned above, and other objectives not explicitly stated will be clearly understood by those skilled in the art based on the following description.

According to various aspects of the present disclosure, a display device includes: an inorganic encapsulation area surrounding a through-hole; a wiring area surrounding the inorganic encapsulation area; and a display area surrounding the wiring area. The inorganic encapsulation area includes: a first organic film including a first sub-organic film having a first opposing inclined surface and a second sub-organic film having a second opposing inclined surface facing the first opposing inclined surface; a first groove formed between the first sub-organic film and the second sub-organic film; and a protrusion formed by at least a portion of the first organic film that is raised between the first sub-organic film and the second sub-organic film.

According to various aspects of the present disclosure, the inorganic encapsulation area may further include: a second organic film positioned on the first organic film; and a plurality of tips each including an exposed portion defined by the first and second organic films.

According to various aspects of the present disclosure, the plurality of tips may include a first tip positioned between the first sub-organic film and the second organic film.

According to various aspects of the present disclosure, the display area may include: a first organic film including the same material as the first organic film in the inorganic encapsulation area; a second connection electrode positioned on the first organic film and including the same material as the first tip; a second organic film positioned on the second connection electrode and including the same material as the second organic film in the inorganic encapsulation area; a plurality of pixel electrodes positioned on the second organic film; a common electrode positioned on the plurality of pixel electrodes; and light-emitting layers positioned between the plurality of pixel electrodes and the common electrode.

According to various aspects of the present disclosure, the plurality of tips may further include a second tip facing the first tip and positioned between the second sub-organic film and the second organic film.

According to various aspects of the present disclosure, a portion of the first tip, exposed by the first sub-organic film and the second organic film, has a first exposure length, a portion of the second tip, exposed by the second sub-organic film and the second organic film, has a second exposure length, and a sum of the first and second exposure lengths may be smaller than a width of the first groove.

According to various aspects of the present disclosure, the first groove has an inverse-taper shape, the first groove has a first width and a second width, the second width is greater than the first width, and the sum of the first and second exposure lengths may be smaller than the second width.

According to various aspects of the present disclosure, a lower surface of the first tip and the first opposing inclined surface form a first angle, and the first angle may be equal to or greater than 45 degrees and less than 90 degrees.

According to various aspects of the present disclosure, a portion of the first tip, exposed by the first sub-organic film and the second organic film, has a first exposure length, and the first exposure length may be greater than 0 μm and less than 2 μm.

According to various aspects of the present disclosure, the first groove has an inverse-taper shape, the first groove has a first width and a second width, the second width is greater than the first width, and the second width may be greater than 0 μm and equal to or less than 8 μm.

According to various aspects of the present disclosure, the inorganic encapsulation area may further include a depression formed between the first opposing inclined surface and the protrusion.

According to various aspects of the present disclosure, the display area includes: a plurality of pixel electrodes; a common electrode positioned on the plurality of pixel electrodes; and light-emitting layers positioned between the plurality of pixel electrodes and the common electrode, and the inorganic encapsulation area may further include a first residual positioned in the first groove and including the same material as the light-emitting layers.

According to various aspects of the present disclosure, the inorganic encapsulation area may further include a second residual positioned on the first residual and including the same material as the common electrode.

According to various aspects of the present disclosure, the inorganic encapsulation area may further include a first inorganic encapsulation film that covers at least a portion of the first opposing inclined surface, at least a portion of the second opposing inclined surface, and the second residual.

According to various aspects of the present disclosure, the inorganic encapsulation area may further include a first inorganic encapsulation film that simultaneously covers at least a portion of the first opposing inclined surface, at least a portion of the depression, and at least a portion of the protrusion.

According to various aspects of the present disclosure, an electronic device includes: a processor configured to provide an image signal; a display module configured to receive the image signal from the processor and display an image; and a power module configured to supply power to the display module. The display module includes: an inorganic encapsulation area surrounding a through-hole; a wiring area surrounding the inorganic encapsulation area; and a display area surrounding the wiring area. The inorganic encapsulation area includes: a first organic film including a first sub-organic film having a first opposing inclined surface and a second sub-organic film having a second opposing inclined surface facing the first opposing inclined surface; a first groove formed between the first sub-organic film and the second sub-organic film; and a protrusion formed by at least a portion of the first organic film that is raised between the first sub-organic film and the second sub-organic film.

According to various aspects of the present disclosure, the inorganic encapsulation area may further include: a second organic film positioned on the first organic film; and a plurality of tips each including an exposed portion defined by the first and second organic films, and the plurality of tips may include a first tip positioned between the first sub-organic film and the second organic film.

According to various aspects of the present disclosure, the inorganic encapsulation area may further include a depression formed between the first opposing inclined surface and the protrusion.

According to various aspects of the present disclosure, the display area includes: a plurality of pixel electrodes; a common electrode positioned on the plurality of pixel electrodes; and light-emitting layers positioned between the plurality of pixel electrodes and the common electrode, and the inorganic encapsulation area may include: a first residual positioned in the first groove and including the same material as the light-emitting layers; and a second residual positioned on the first residual and including the same material as the common electrode.

According to various aspects of the present disclosure, the inorganic encapsulation area may further include a first inorganic encapsulation film that simultaneously covers at least a portion of the first opposing inclined surface, at least a portion of the depression, and at least a portion of the protrusion.

According to the present disclosure, the adhesion strength of the encapsulation layer can be improved by a plurality of tips and grooves, thereby preventing damage caused by detachment of the protective film during the manufacturing process.

It should be noted that the effects of the present disclosure are not limited to those described above, and additional effects will be apparent from the following description.

### BRIEF DESCRIPTION OF THE DRAWINGS

The above and other features of the present disclosure will become more apparent by describing aspects thereof in detail with reference to the attached drawings, in which:

FIG. 1 is a plan view illustrating a display panel and a driver IC according to an aspect of the present disclosure;

FIG. 2 is a cross-sectional view illustrating an example of a display device in which a circuit board is bent, according to an aspect of the present disclosure;

FIG. 3 is a cross-sectional view illustrating an example of a display area of a display panel according to an aspect of the present disclosure;

FIGS. 4 and 5 are cross-sectional views illustrating steps in a manufacturing process of the display device according to an aspect of the present disclosure;

FIG. 6 is a cross-sectional view illustrating the display device according to an aspect of the present disclosure;

FIG. 7 is a partially enlarged view of region I of FIG. 1;

FIG. 8 is a partially enlarged view of region J of FIG. 7;

FIG. 9 is a partially enlarged view of region K of FIG. 8;

FIG. 10 is a cross-sectional view illustrating an aspect of the display panel cut along line X-X' of FIG. 9;

FIG. 11 is a partially enlarged view of region L of FIG. 10;

FIG. 12 is a partially enlarged view of a portion of region L of FIG. 11;

FIGS. 13 and 14 are partially enlarged views illustrating the shapes after deformation in the structures depicted in FIGS. 11 and 12;

FIGS. 15 through 17 are cross-sectional views illustrating steps in a process of forming the display device according to an aspect of the present disclosure;

FIG. 18 is a block diagram of an electronic device according to an aspect of the present disclosure; and

FIG. 19 presents a set of schematic views of electronic devices according to various aspects of the present disclosure.

### DETAILED DESCRIPTION

The advantages and features of the aspects disclosed herein, and methods of achieving them, will become apparent upon reference to the aspects described in detail with accompanying drawings. However, the technical features of the present disclosure are not limited to the aspects disclosed herein, but may take many different forms, and these aspects are provided merely to make the disclosure complete and to fully inform one of ordinary skill in the art to which the present disclosure belongs. It should be understood that the present disclosure is defined by the scope of the claims.

References to an element or layer as being “on” another element or layer include both cases in which another layer or element is directly on top of or interposed between other elements. Throughout this specification, like reference numerals refer to like components. The shapes, sizes, proportions, angles, numbers, etc. disclosed in the drawings to illustrate aspects are exemplary and are not intended to be limiting to those shown herein.

Although first, second, and the like are used to describe various components, the components are not limited by these terms. Thus, a first component referred to herein may also be a second component within the technical idea of the present disclosure.

Each of the features of the various aspects disclosed herein may be combined or combinable with each other, in part or in whole, and may be technically interlocked and operated in a variety of ways, and each aspect may be practiced independently of or in conjunction with one another.

Specific aspects will be described below with reference to the accompanying drawings. Configurations that function substantially the same between aspects are given the same drawing designation and repeated description is omitted.

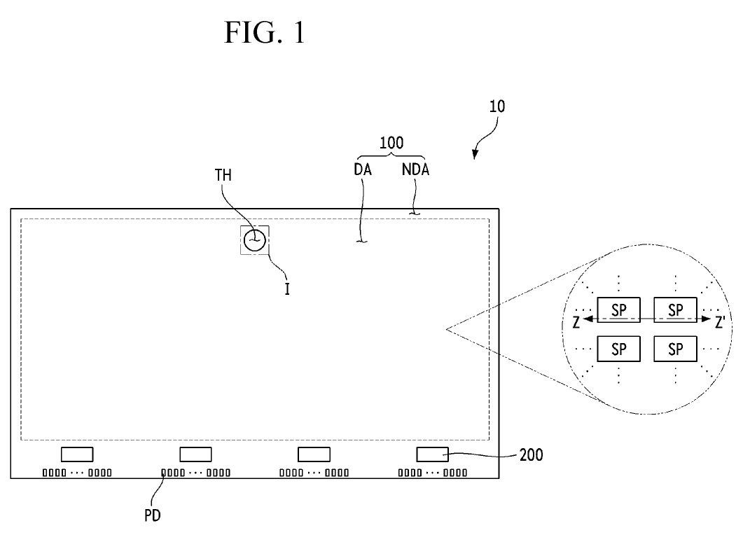

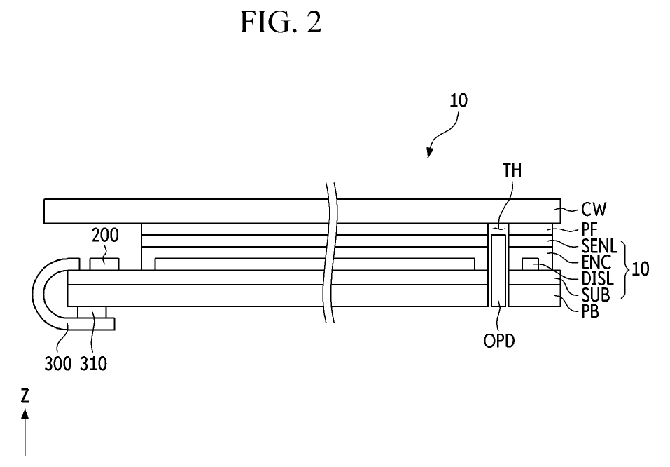

FIG. 1 is a plan view illustrating a display panel and a driver IC according to an aspect of the present disclosure. FIG. 2 is a cross-sectional view illustrating an example of a display device in which a circuit board is bent, according to an aspect of the present disclosure.

Referring to FIGS. 1 and 2, a display device 10 according to an aspect of the present disclosure may include a through-hole TH. The through-hole TH is a hole that can transmit light and may be a physical hole penetrating not only a display panel 100 but also a panel bottom cover PB and a polarizing film PF, but is not limited thereto. Alternatively, the through-hole TH may penetrate the panel bottom cover PB but not the display panel 100 or the polarizing film PF. A cover window CW may be arranged to cover the through-hole TH.

The through-hole TH may penetrate a substrate SUB, a thin-film transistor layer TFTL, an encapsulation layer ENC, and a sensor electrode layer SENL of the display panel 100.

An electronic device including the display device 10, according to an aspect, may further include an optical device OPD positioned in the through-hole TH. The electronic device according to an aspect may be not only a portable electronic device such as a mobile phone, a smart phone, a tablet personal computer, a smart watch, a watch phone, a mobile communication terminal, an electronic notebook, an electronic book reader, a portable multimedia player (PMP), a navigation device, or an ultra-mobile PC (UMPC), but also a television, a notebook computer, a monitor, a digital signage, or an Internet of Things (IoT) device, but is not limited thereto.

The optical device OPD may be spaced apart from the display panel 100, the panel bottom cover PB, and the polarizing film PF. The optical device OPD may be an optical sensor for detecting light incident through the through-hole TH, such as a proximity sensor, an illuminance sensor, or a camera sensor.

Referring to FIG. 2, the display device 10 may include a display panel 100, a polarizing film PF, a cover window CW, and a panel bottom cover PB. The display panel 100 may include a substrate SUB, a display layer DISL, an encapsulation layer ENC, and a sensor electrode layer SENL.

The substrate SUB may include a rigid material. For example, the substrate SUB may include glass. The substrate SUB may include ultra-thin glass (UTG) having a thickness of approximately 200 μm or less.

The substrate SUB may include a flexible material. For example, the substrate SUB may include polyimide.

The display layer DISL may be positioned on a first surface of the substrate SUB. The display layer DISL may be a layer that displays an image. The display layer DISL may include a thin-film transistor layer TFTL on which thin-film transistors are formed, and a light-emitting element layer EML in which light-emitting elements are arranged in light-emitting areas.

In a display area DA of the display layer DISL, scan lines, data lines, and power lines for enabling light to be emitted from the light-emitting areas may be arranged. In a non-display area NDA of the display layer DISL, a scan driver circuit unit that outputs scan signals to the scan lines, and fan-out lines that connect the data lines to a driver IC 200 may be arranged.

The encapsulation layer ENC may prevent oxygen and/or moisture from penetrating into the light-emitting element layer EML of the display layer DISL. The encapsulation layer ENC may be a layer for encapsulating the light-emitting element layer EML of the display layer DISL. The encapsulation layer ENC may be arranged on the display layer DISL. The encapsulation layer ENC may be arranged on the upper surface and side surfaces of the display layer DISL. The encapsulation layer ENC may be arranged to cover the display layer DISL.

The sensor electrode layer SENL may be arranged on the display layer DISL. The sensor electrode layer SENL may include sensor electrodes. The sensor electrode layer SENL may detect a user’s touch using the sensor electrodes.

A polarizing film PF may be arranged on the display panel 100 to reduce external light reflection. The polarizing film PF may include a first base member, a linear polarizer, a phase retardation film (e.g., a quarter-wave plate), and a second base member. The first base member, the phase retardation film, the linear polarizer, and the second base member of the polarizing film PF may be sequentially stacked on the display panel 100.

The cover window CW may be arranged on the polarizing film PF. The cover window CW may be attached to the polarizing film PF by a transparent adhesive member such as an optically clear adhesive (OCA) film.

The panel bottom cover PB may be arranged on a second surface of the substrate SUB of the display panel 100. The second surface of the substrate SUB may be a surface opposite to the first surface. The panel bottom cover PB may be attached to the second surface of the substrate SUB of the display panel 100 via an adhesive member. The adhesive member may be a pressure sensitive adhesive (PSA).

The panel bottom cover PB may include at least one of a light-shielding member for absorbing light incident from the outside, a buffer member for absorbing external impact, and a heat dissipation member for efficiently dissipating heat from the display panel 100.

The light-shielding member may be arranged below the display panel 100. The light-shielding member may block transmission of light and prevent components arranged below the light-shielding member, such as a circuit board 300, from being visible from the top of the display panel 100. The light-shielding member may include a light-absorbing material such as black pigment or black dye.

The buffer member may be arranged below the light-shielding member. The buffer member may absorb external impact and prevent the display panel 100 from being damaged. The buffer member may include a single layer or multiple layers. For example, the buffer member may contain a polymer resin such as polyurethane, polycarbonate, polypropylene, or polyethylene, or may contain an elastic material such as a sponge formed by foaming rubber, a urethane-based material, or an acrylic-based material.

The heat dissipation member may be arranged below the buffer member. The heat dissipation member may include a first heat dissipation layer containing graphite or carbon nanotubes, and a second heat dissipation layer containing a metal thin film having excellent thermal conductivity and capable of shielding electromagnetic waves, such as copper, nickel, ferrite, or silver.

The circuit board 300 may be bent toward the lower portion of the display panel 100. The circuit board 300 may be attached to a lower surface of the panel bottom cover PB by an adhesive member 310. The adhesive member 310 may be a PSA.

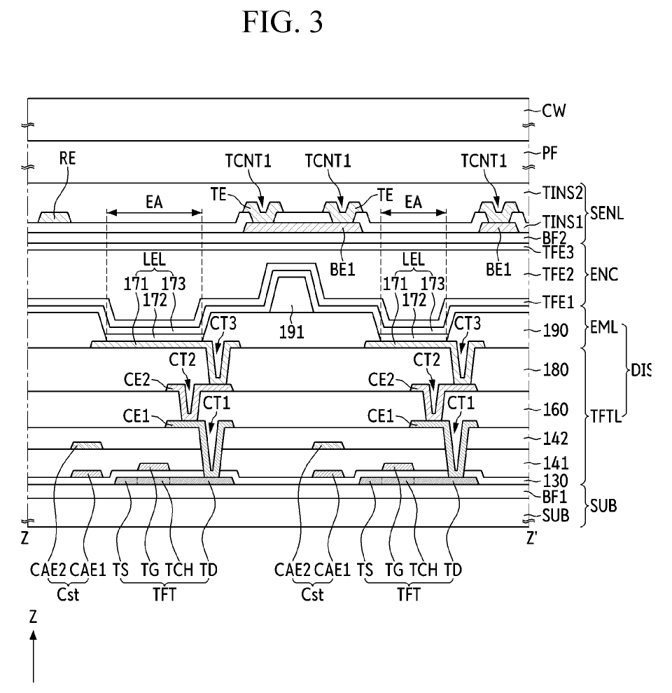

FIG. 3 is a cross-sectional view illustrating an example of a display area of a display panel according to an aspect of the present disclosure. FIG. 3 may also be an illustration of an example of a display panel cut along line Z–Z' of FIG. 1.

Referring to FIG. 3, a display panel 100 according to an aspect of the present disclosure may be an organic light-emitting display panel including a light-emitting element LEL that includes an organic light-emitting layer 172.

The display layer DISL may include a thin-film transistor layer TFTL including a plurality of thin-film transistors and a light-emitting element layer EML including a plurality of light-emitting elements.

A first buffer film BF1 may be positioned on the substrate SUB. The first buffer film BF1 may include an inorganic material such as a silicon nitride layer, a silicon oxynitride layer, a silicon oxide layer, a titanium oxide layer, or an aluminum oxide layer. Alternatively, the first buffer film BF1 may be formed as a multilayer film in which a plurality of layers among a silicon nitride layer, a silicon oxynitride layer, a silicon oxide layer, a titanium oxide layer, or an aluminum oxide layer are alternately stacked.

An active layer including channel regions TCH, source regions TS, and drain regions TD of thin-film transistors TFT may be positioned on the first buffer film BF1. The active layer may be formed of polycrystalline silicon, monocrystalline silicon, low-temperature polycrystalline silicon, amorphous silicon, or an oxide semiconductor material. When the active layer includes polycrystalline silicon or an oxide semiconductor material, the source regions TS and the drain regions TD of the active layer may be conductive regions doped with ions or impurities to have conductivity.

A gate insulating film 130 may be positioned on the active layer of the thin-film transistors TFT. The gate insulating film 130 may include an inorganic film, for example, a silicon nitride layer, a silicon oxynitride layer, a silicon oxide layer, a titanium oxide layer, or an aluminum oxide layer.

A first gate metal layer including gate electrodes TG of the thin-film transistors TFT, first capacitor electrodes CAE1 of capacitors Cst, and scan lines may be positioned on the gate insulating film 130. The gate electrodes TG of the thin-film transistors TFT may overlap the channel regions TCH in a third direction (e.g., a Z-axis direction). The first gate metal layer may be formed as a single layer or a multilayer of one or more of molybdenum (Mo), aluminum (Al), chromium (Cr), gold (Au), titanium (Ti), nickel (Ni), neodymium (Nd), and copper (Cu), or an alloy thereof.

A first interlayer insulating film 141 may be positioned on the first gate metal layer. The first interlayer insulating film 141 may include an inorganic film, for example, a silicon nitride layer, a silicon oxynitride layer, a silicon oxide layer, a titanium oxide layer, or an aluminum oxide layer. The first interlayer insulating film 141 may include a plurality of inorganic films.

A second gate metal layer including second capacitor electrodes CAE2 of the capacitors Cst may be positioned on the first interlayer insulating film 141. The second capacitor electrodes CAE2 may overlap the first capacitor electrodes CAE1 in the third direction (e.g., the Z-axis direction). Accordingly, the capacitors Cst may be formed by the first capacitor electrodes CAE1, the second capacitor electrodes CAE2, and an inorganic insulating dielectric film that serves as a dielectric layer between the first capacitor electrodes CAE1 and the second capacitor electrodes CAE2. The second gate metal layer may be formed as a single layer or a multilayer of one or more of Mo, Al, Cr, Au, Ti, Ni, Nd, and Cu, or an alloy thereof.

A second interlayer insulating film 142 may be positioned on the second gate metal layer. The second interlayer insulating film 142 may include an inorganic film, for example, a silicon nitride layer, a silicon oxynitride layer, a silicon oxide layer, a titanium oxide layer, or an aluminum oxide layer. The second interlayer insulating film 142 may include a plurality of inorganic films.

A first data metal layer including first connection electrodes CE1 and data lines may be positioned on the second interlayer insulating film 142. The first connection electrodes CE1 may be connected to the drain regions TD through first contact holes CT1 penetrating the gate insulating film 130, the first interlayer insulating film 141, and the second interlayer insulating film 142. The first data metal layer may be formed as a single layer or a multilayer of one or more of Mo, Al, Cr, Au, Ti, Ni, Nd, and Cu, or an alloy thereof.

A first organic film 160 for planarizing steps formed by the thin-film transistors TFT may be positioned on the first connection electrodes CE1. The first organic film 160 may include an organic film such as acryl resin, epoxy resin, phenolic resin, polyamide resin, or polyimide resin.

A second data metal layer including second connection electrodes CE2 may be positioned on the first organic film 160. The second data metal layer may be connected to the first connection electrodes CE1 through second contact holes CT2 penetrating the first organic film 160. The second data metal layer may be formed as a single layer or a multilayer of one or more of Mo, Al, Cr, Au, Ti, Ni, Nd, and Cu, or an alloy thereof.

A second organic film 180 may be positioned on the second connection electrodes CE2. The second organic film 180 may include an organic film such as acryl resin, epoxy resin, phenolic resin, polyamide resin, or polyimide resin.

The second data metal layer, including the second connection electrodes CE2, and the second organic film 180 may be omitted.

A light-emitting element layer EML may be positioned on the thin-film transistor layer TFTL. The light-emitting element layer EML may include light-emitting elements LEL and a bank 190.

Each of the light-emitting elements LEL may include a pixel electrode 171, a light-emitting layer 172, and a common electrode 173. Light-emitting areas EA may be areas in which the pixel electrodes 171, the light-emitting layers 172, and the common electrodes 173 are sequentially stacked such that holes from the pixel electrodes 171 and electrons from the common electrode 173 recombine in the light-emitting layers 172 to emit light. In this case, the pixel electrodes 171 may serve as anodes, and the common electrode 173 may serve as a cathode.

A pixel electrode layer including the pixel electrodes 171 may be formed on the second organic film 180. The pixel electrodes 171 may be connected to the second connection electrodes CE2 through third contact holes CT3 penetrating the second organic film 180. The pixel electrode layer may be formed as a single layer or a multilayer of one or more of Mo, Al, Cr, Au, Ti, Ni, Nd, and Cu, or an alloy thereof.

In a top emission structure in which light is emitted toward the common electrode 173 from the light-emitting layers 172, the pixel electrodes 171 may be formed as single layers of Mo, Ti, Cu, or Al, or as stacked structures to increase reflectance, such as Ti/Al/Ti, ITO/Al/ITO, or ITO/APC/ITO. Here, APC is an alloy of silver (Ag), palladium (Pd), and Cu.

The bank 190 serves to define the light-emitting areas EA of pixels. To this end, the bank 190 may be formed on the second organic film 180 to expose portions of the pixel electrodes 171. The bank 190 may cover the edges of the pixel electrodes 171. The bank 190 may be positioned within the third contact holes CT3. That is, the third contact holes CT3 may be filled with the bank 190. The bank 190 may include an organic film such as acryl resin, epoxy resin, phenolic resin, polyamide resin, or polyimide resin.

A spacer 191 may be positioned on the bank 190. The spacer 191 may serve to support a mask during the fabrication of the light-emitting layers 172. The spacer 191 may include an organic film such as acryl resin, epoxy resin, phenolic resin, polyamide resin, or polyimide resin.

The light-emitting layers 172 may be formed on the pixel electrodes 171. The light-emitting layers 172 may emit a predetermined color by including an organic material. For example, the light-emitting layers 172 may include hole transporting layers, organic material layers, and electron transporting layers. The organic material layers may include a host and a dopant. The organic material layers may include a material for emitting predetermined light and may be formed using a phosphorescent material or a fluorescent material.

The common electrode 173 may be formed on the light-emitting layers 172. The common electrode 173 may be formed to cover the light-emitting layers 172. The common electrode 173 may be a common layer commonly formed over the light-emitting areas EA. A capping layer may be formed on the common electrode 173.

In a top emission structure, the common electrode 173 may include a transparent conductive oxide (TCO) material such as ITO or IZO, which transmits light, or a semi-transmissive conductive material such as magnesium (Mg), Ag, or an alloy thereof. When the common electrode 173 includes a semi-transmissive conductive material, the light emission efficiency may be enhanced due to a microcavity effect.

The encapsulation layer ENC may be formed on the light-emitting element layer EML. The encapsulation layer ENC may include at least one inorganic film (TFE1 and TFE3) to prevent oxygen or moisture from penetrating into the light-emitting element layer EML. In addition, the encapsulation layer ENC may include at least one organic film to protect the light-emitting element layer EML from foreign substances such as dust. For example, the encapsulation layer ENC may include a first inorganic encapsulation film TFE1, an organic encapsulation film TFE2, and a second inorganic encapsulation film TFE3.

The first inorganic encapsulation film TFE1 may be positioned on the common electrode 173, the organic encapsulation film TFE2 may be positioned on the first inorganic encapsulation film TFE1, and the second inorganic encapsulation film TFE3 may be positioned on the organic encapsulation film TFE2. The first and second inorganic encapsulation films TFE1 and TFE3 may be formed as multilayer films in which one or more of a silicon nitride layer, a silicon oxynitride layer, a silicon oxide layer, a titanium oxide layer, and an aluminum oxide layer are alternately stacked. The organic encapsulation film TFE2 may include an organic film such as acryl resin, epoxy resin, phenolic resin, polyamide resin, or polyimide resin.

The sensor electrode layer SENL is positioned on the encapsulation layer ENC. The sensor electrode layer SENL may include sensor electrodes (TE and RE).

A second buffer film BF2 may be positioned on the encapsulation layer ENC. The second buffer film BF2 may include at least one inorganic film. For example, the second buffer film BF2 may be formed as a multilayer film in which one or more of a silicon nitride layer, a silicon oxynitride layer, a silicon oxide layer, a titanium oxide layer, and an aluminum oxide layer are alternately stacked. The second buffer film BF2 may be omitted.

First connection portions BE1 may be positioned on the second buffer film BF2. The first connection portions BE1 may be formed as single layers of Mo, Ti, Cu, or Al, or as stacked structures of Ti/Al/Ti, ITO/Al/ITO, or ITO/APC/ITO.

A first sensor insulating film TINS1 may be positioned on the first connection portions BE1. The first sensor insulating film TINS1 may include an inorganic film such as a silicon nitride layer, a silicon oxynitride layer, a silicon oxide layer, a titanium oxide layer, or an aluminum oxide layer.

The sensor electrodes (TE and RE), i.e., driving electrodes TE and sensing electrodes RE, may be positioned on the first sensor insulating film TINS1. In addition, dummy patterns may be positioned on the first sensor insulating film TINS1. The driving electrodes TE, sensing electrodes RE, and dummy patterns do not overlap the light-emitting areas EA. The driving electrodes TE, sensing electrodes RE, and dummy patterns may be formed as single layers of Mo, Ti, Cu, or Al, or as stacked structures of Ti/Al/Ti, ITO/Al/ITO, or ITO/APC/ITO.

A second sensor insulating film TINS2 may be positioned on the driving electrodes TE, the sensing electrodes RE, and the dummy patterns. The second sensor insulating film TINS2 may include at least one of an inorganic film and an organic film. The inorganic film may be a silicon nitride layer, a silicon oxynitride layer, a silicon oxide layer, a titanium oxide layer, or an aluminum oxide layer. The organic film may be an acryl resin, an epoxy resin, a phenolic resin, a polyamide resin, or a polyimide resin.

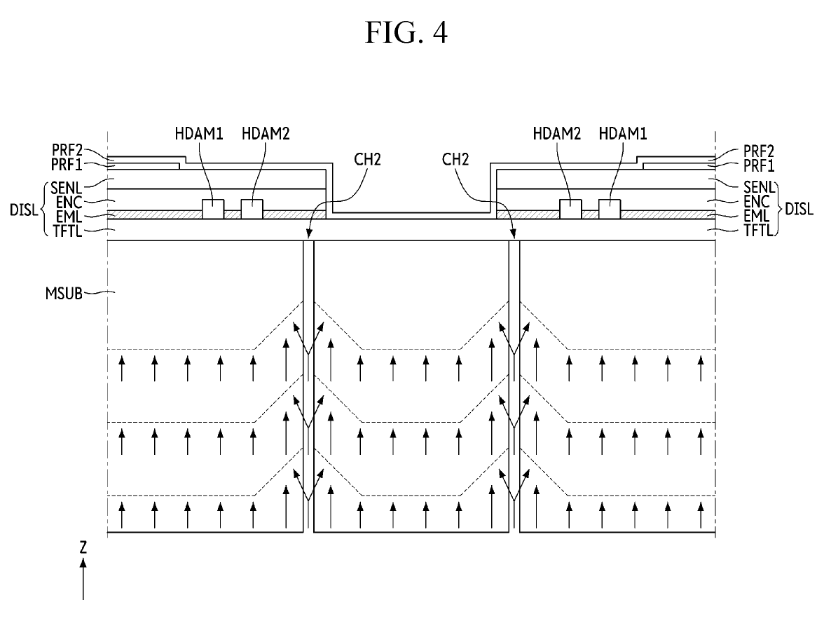

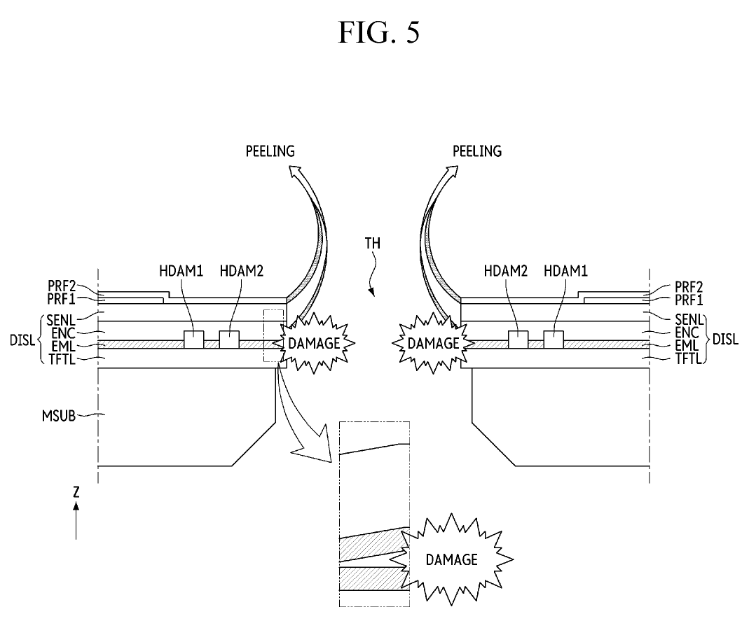

FIGS. 4 and 5 are cross-sectional views illustrating steps in a manufacturing process of a display device according to an aspect of the present disclosure.

The manufacturing process of the display device according to an aspect of the present disclosure may include a plurality of steps.

As one step, a plurality of display cells may be formed on a first surface of a mother substrate MSUB.

As a subsequent step, a plurality of first protective films PRF1 may be attached to the display cells. Each of the first protective films PRF1 may be a buffer film for protecting the display cells from external impact. The first protective films PRF1 may include a transparent material. Also, the display cells may be inspected.

As a subsequent step, a first laser may be irradiated onto a second surface of the mother substrate MSUB, which faces the first surface. A plurality of first laser irradiation regions may be formed along edges of the display cells. In an aspect, various types of lasers may be used as the first laser.

A laser for forming the first laser irradiation region may be irradiated at a repetition rate of 10 kHz to 250 kHz, a processing speed of 10 mm/s to 250 mm/s, and a pulse energy of 10 μJ to 300 μJ. However, in order to have a depth of approximately 225 μm from the first surface of the mother substrate MSUB, the first laser may be irradiated, for example, at a repetition rate of approximately 17.5 kHz to 125 kHz, a processing speed of 17.5 mm/s to 125 mm/s, and a pulse energy of 25 μJ to 178 μJ.

As a subsequent step, a second laser may be irradiated onto the second surface of the mother substrate MSUB. A plurality of second laser irradiation regions CH2 for forming through-holes in the respective display cells may be formed. In one aspect, to shorten processing time, the first and second lasers may be irradiated simultaneously using a plurality of laser devices.

A second cutting line may be defined as a virtual line connecting the second laser irradiation regions CH2 on a plane. The second cutting line may be formed by irradiating the second laser to form the second laser irradiation regions CH2 along the edge of a through-hole TH. The second cutting line may depend on the shape and/or form of the through-hole. For example, when the through-hole TH has a circular planar shape, the second cutting line may be formed in a circular shape.

Although various types of lasers may be used as the first laser and the second laser according to an aspect, in the present disclosure, the first laser and the second laser are exemplified as Bessel beams of the infrared range having a wavelength of approximately 1030 nm.

The depth of the first laser irradiation regions formed by the first laser and the depth of the second laser irradiation regions CH2 formed by the second laser may differ. The depth of the first laser irradiation regions may be defined as the depth (or sketch length) of the first laser irradiation region, and the depth of the second laser irradiation region CH2 may be defined as the depth (or sketch length) of the second laser irradiation region CH2.

As a subsequent step, referring to FIG. 4, a second protective film PRF2 may be attached on the first protective films PRF1.

The second protective film PRF2 may be attached onto the first protective films PRF1 and the exposed portions of the mother substrate MSUB that are not covered by the first protective films PRF1. The second protective film PRF2 may cover the first laser irradiation regions and the second laser irradiation regions CH2. The second protective film PRF2 may be an acid-resistant film for protecting the display cells from an etchant in an etching process to be performed on the mother substrate MSUB in a subsequent step.

As a subsequent step, referring to FIG. 4, an etchant may be sprayed onto the second surface of the mother substrate MSUB without a separate mask. Accordingly, the thickness of the mother substrate MSUB may be reduced.

Additionally, the mother substrate MSUB may be cut along the first laser irradiation regions and the second laser irradiation regions CH2.

When an etchant is sprayed onto the second surface of the mother substrate MSUB, the thickness of the mother substrate MSUB may be reduced from a first thickness to a second thickness. Since the mother substrate MSUB is etched without a separate mask, the mother substrate MSUB may be uniformly etched over its entire second surface.

Each of the second laser irradiation regions CH2 may include a physical hole formed by the second laser and a region around the physical hole in which the physical property has been changed by the second laser. Alternatively, each of the second laser irradiation regions CH2 may be a region in which the physical property has been changed by the second laser without a physical hole. Accordingly, the etching rate at each of the second laser irradiation regions CH2 by the etchant may be higher than the etching rate in other regions of the mother substrate MSUB where the second laser has not been irradiated.

Since the depth of each of the second laser irradiation regions CH2 is greater than the depth of the first laser irradiation regions, the etchant may penetrate into the second laser irradiation regions CH2 earlier than into the first laser irradiation regions. That is, as the thickness of the mother substrate MSUB is reduced by a slimming process using the etchant, the second laser irradiation regions CH2 are etched, and a tapered cross-section by isotropic etching may be formed at a substrate SUB, within the through-hole TH formed by the second laser irradiation regions CH2. In contrast, etching may not proceed in the first laser irradiation regions during the slimming process.

As a subsequent step, referring to FIG. 5, after the etching process is completed, the second protective film PRF2 may be detached. In addition, a driver IC and a circuit board may be attached to each of the plurality of display cells, and the first protective films PRF1 may be detached from the display cells.

During the process of detaching the second protective film PRF2, one side of the cut second protective film PRF2 may be lifted. The lifted side may be adjacent to the through-hole TH.

When detaching one side of the second protective film PRF2, the adhesive force between the second protective film PRF2 and a display layer DISL may affect the components positioned below the second protective film PRF2. For example, a light-emitting element layer EML positioned below the second protective film PRF2 may tear during the detachment of the second protective film PRF2 positioned thereon. The light-emitting element layer EML may have a smaller length in a thickness direction (e.g., the Z-axis direction) compared to other components, e.g., a sensor electrode layer SENL and an encapsulation layer ENC. For example, light-emitting layers positioned in the light-emitting element layer EML may have a very small thickness. Therefore, tearing damage caused by the adhesive force of the second protective film PRF2 may occur relatively frequently.

Referring to an enlarged view, when one side of the light-emitting element layer EML is separated into upper and lower parts, sides of the sensor electrode layer SENL and the encapsulation layer ENC may be lifted in the upper direction of the display device along with the upper part of the light-emitting element layer EML. A gap may be generated between the upper and lower parts of the light-emitting element layer EML.

Moisture or oxygen may penetrate through the gap in the light-emitting element layer EML caused during the detachment of the second protective film PRF2, which may affect the display area. As a result, the durability of the display device may be reduced.

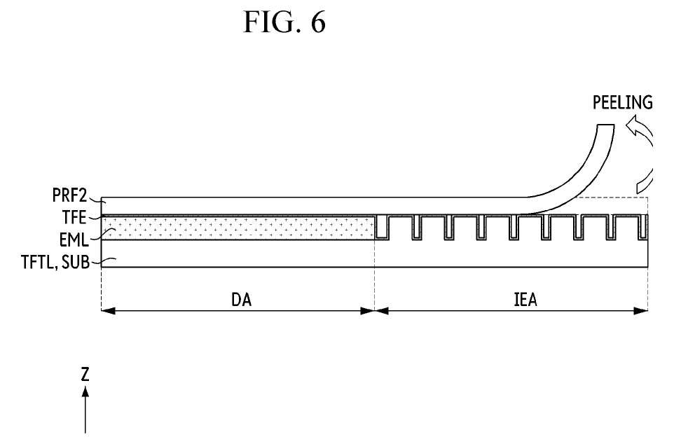

FIG. 6 is a cross-sectional view illustrating the display device according to an aspect of the present disclosure.

Referring to FIG. 6, the display device according to an aspect of the present disclosure may include an inorganic encapsulation area IEA. A display area DA may include a substrate SUB, and a light-emitting element layer EML and an encapsulation layer ENC that are arranged on the substrate SUB. The light-emitting element layer EML may include light-emitting layers. The inorganic encapsulation area IEA may include the substrate SUB and the encapsulation layer ENC positioned on the substrate SUB. The inorganic encapsulation area IEA may also include light-emitting layers. The light-emitting layers positioned in the inorganic encapsulation area IEA may not actually emit light, but may be light-emitting layer residuals (or first residuals) that remain after the arrangement of light-emitting layers over an entire display panel. The substrate SUB may be derived from the aforementioned mother substrate MSUB.

The impact on the light-emitting element layer EML may be reduced during detachment of a second protective film PRF2 by using the encapsulation layer ENC positioned in the inorganic encapsulation area IEA. For example, in the display device according to an aspect of the present disclosure, the adhesive force between the encapsulation layer ENC positioned in the inorganic encapsulation area IEA and components below the encapsulation layer ENC, e.g., a thin-film transistor layer TFTL and the substrate SUB, may be enhanced, and thus, the light-emitting layers positioned in the inorganic encapsulation area IEA may not be separated. Accordingly, moisture or oxygen from the outside may not penetrate, and pixels positioned in the display area DA may be protected.

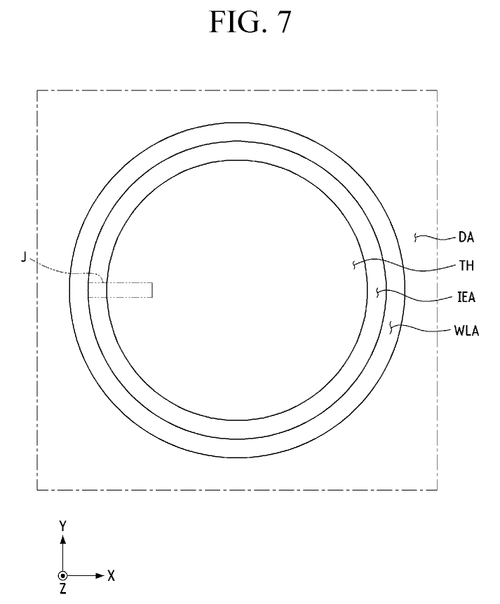

FIG. 7 is a partially enlarged view of region I of FIG. 1.

Referring to FIG. 7, the display panel may include an inorganic encapsulation area IEA surrounding the through-hole TH and a wiring area WLA surrounding the inorganic encapsulation area IEA.

The inorganic encapsulation area IEA may be a layer for preventing oxygen or moisture from penetrating into the light-emitting element layer EML of the display layer DISL due to the through-hole TH. For example, as the first and second inorganic encapsulation films TFE1 and TFE3 of the encapsulation layer ENC contact each other, penetration of oxygen or moisture may be prevented.

The inorganic encapsulation area IEA may include at least one dam, at least one tip, and at least one groove.

The wiring area WLA may be an area where detour wirings are arranged due to the presence of the through-hole TH. Some of the detour wirings may be connected to the data lines, and some others may be connected to a second power line to which a second power voltage higher than a first power voltage is applied. Some others of the detour wirings may be connected to the scan lines. The wiring area WLA may be surrounded by a display area DA.

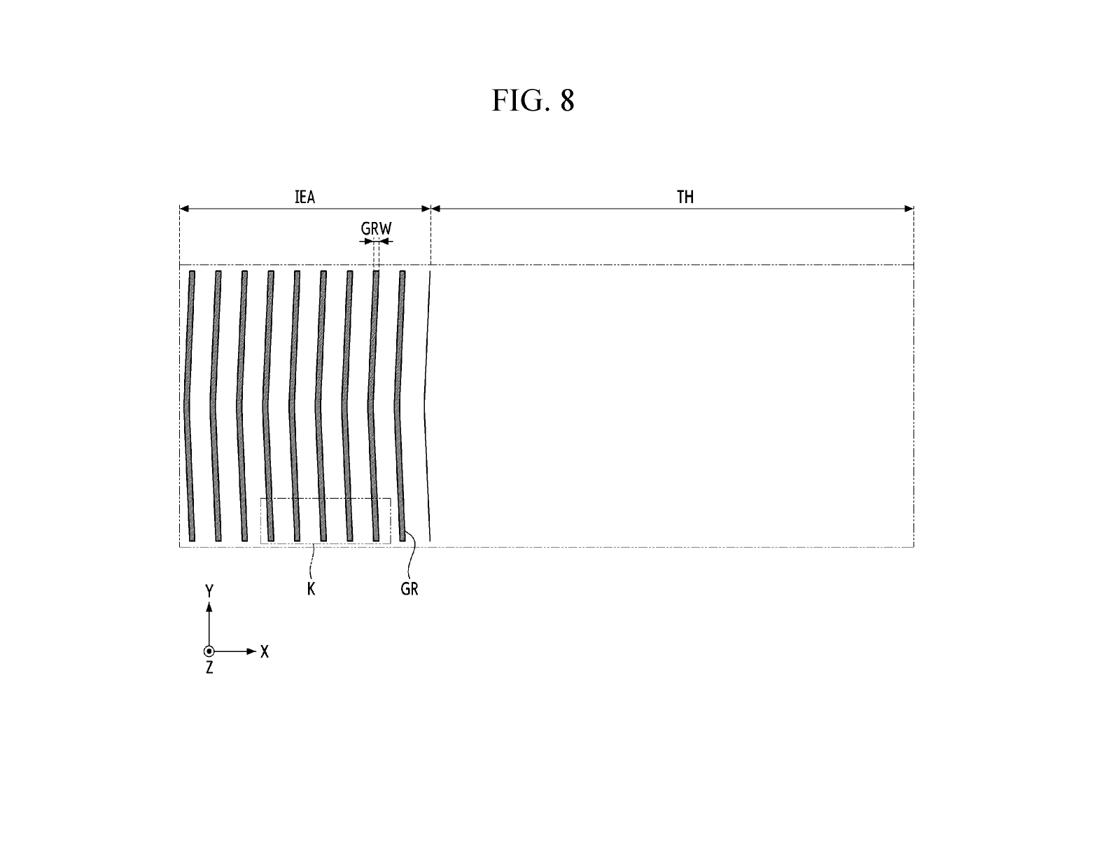

FIG. 8 is a partially enlarged view of region J of FIG. 7.

Referring to FIGS. 7 and 8, the inorganic encapsulation area IEA may include grooves GR. The grooves GR may have a width GRW as a length in one direction. The grooves GR may be formed to surround the through-hole TH in a closed curve shape. A plurality of grooves GR may be formed. Among the plurality of grooves GR, since one groove GR surrounds the through-hole TH in a closed curve shape, it may not include a point of intersection with other grooves GR.

When the through-hole TH is circular in plan view, the grooves GR may appear as straight lines in an enlarged plan view. For example, the grooves GR may be arranged to extend in a second direction (e.g., a Y-axis direction) and may not intersect one another. A dam may be arranged between the grooves GR, and details thereof will be described later.

The adhesion strength of the encapsulation layer ENC may be enhanced by the grooves GR formed in the inorganic encapsulation area IEA. Accordingly, tearing due to detachment of the second protective film PRF2 during the manufacturing process may be prevented.

In one aspect, the width GRW of the grooves GR may be 0.1 μm to 8 μm. By forming the width GRW to be sufficiently small, the adhesion strength of the encapsulation layer ENC may be enhanced. Details of adhesion strength enhancement will be described later.

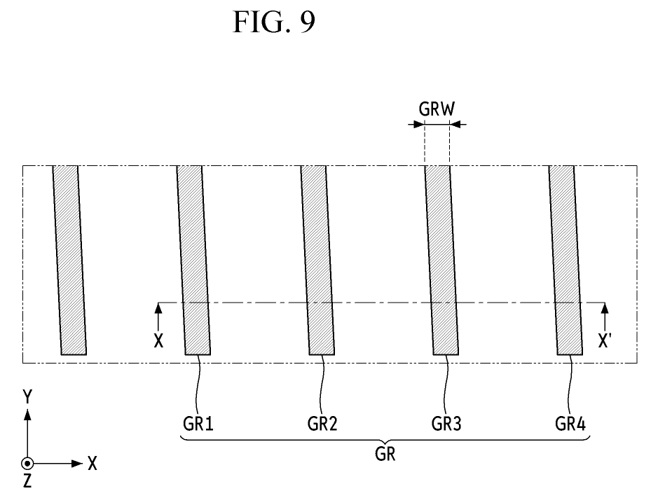

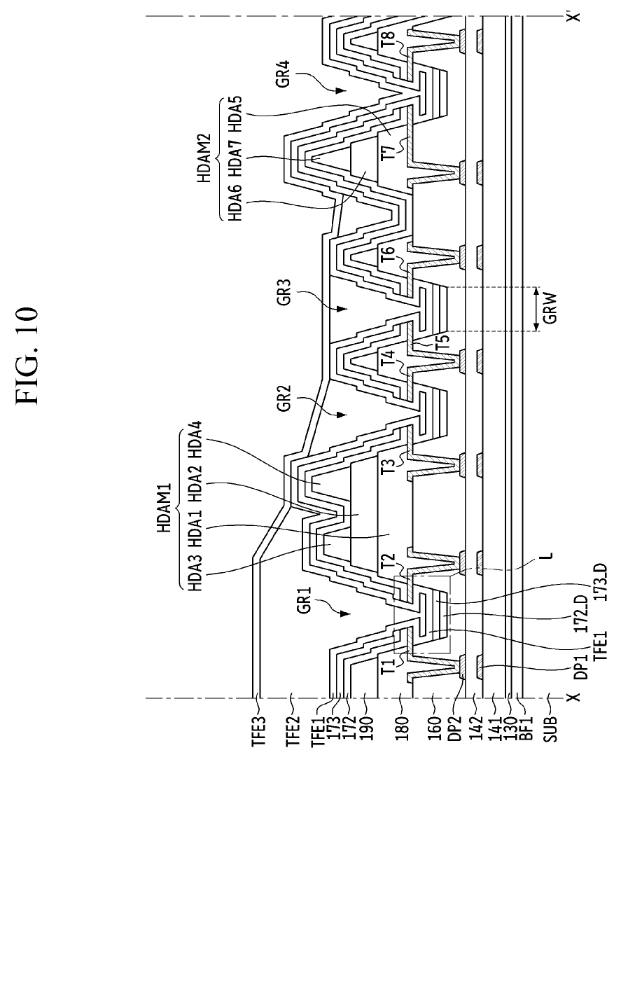

FIG. 9 is a partially enlarged view of region K of FIG. 8. FIG. 10 is a cross-sectional view illustrating an example of the display panel cut along line X–X′ of FIG. 9.

The cross-sectional view taken along line X–X′ includes the light-emitting layers 172, the common electrode 173, the second organic film 180, and the bank 190. Since region K is positioned between the display area DA and the through-hole TH, the light-emitting layers 172, the common electrode 173, the second organic film 180, and the bank 190 may not actually be arranged in region K, but are illustrated to aid understanding of the correlation with the cross-sectional view along line Z–Z′.

For example, in the cross-sectional view along line X-X′, the second organic film 180 may be one sub-dam, the bank 190 may be another sub-dam, the light-emitting layers 172 may be light-emitting layer residuals (or first residuals) that are arranged along the extension of each disconnected area and do not emit light, and the common electrode 173 may be a common electrode residual (or second residual) that is arranged along the extension of each disconnected area and do not perform the functions of an electrode.

However, in order to directly indicate the correlation with the light-emitting elements arranged in the display area DA, reference numerals in the drawings are provided as illustrated for convenience.

Referring to FIGS. 9 and 10, in the inorganic encapsulation area IEA, first dummy patterns DP1 may be positioned on the same layer as, and include the same material as, the second gate metal layer including the second capacitor electrodes CAE2 of the capacitors Cst. For example, the first dummy patterns DP1 may be positioned on the first interlayer insulating film 141. The first dummy patterns DP1 may be formed as single layers or multilayers of one or more of Mo, Al, Cr, Au, Ti, Ni, Nd, or Cu, or an alloy thereof.

Second dummy patterns DP2 may be positioned on the same layer as, and include the same material as, the first data metal layer including the first connection electrodes CE1 and the data lines. For example, the second dummy patterns DP2 may be positioned on the second interlayer insulating film 142. The second dummy patterns DP2 may be formed as single layers or multilayers of one or more of Mo, Al, Cr, Au, Ti, Ni, Nd, or Cu, or an alloy thereof.

The second dummy patterns DP2 may overlap the first dummy patterns DP1 in the third direction (e.g., the Z-axis direction).

First through eighth tips T1 through T8 may be positioned on the same layer as, and include the same material as, the second data metal layer including the second connection electrodes CE2. For example, the first through eighth tips T1 through T8 may be positioned on the first organic film 160. Each of the first through eighth tips T1 through T8 may be formed as single layers or multilayers of one or more of Mo, Al, Cr, Au, Ti, Ni, Nd, or Cu, or an alloy thereof.

The first through eighth tips T1 through T8 may be respectively connected to the second dummy patterns DP2 through contact holes penetrating the first organic film 160. Each of the first through eighth tips T1 through T8 may have an eave structure where its upper and lower surfaces are not covered by the first organic film 160, the second organic film 180, a first dam HDAM1, or a second dam HDAM2. For example, some of the first through eighth tips T1 through T8, e.g., the fourth and fifth tips T4 and T5, may be integrally formed. Each of the first through eighth tips T1 through T8 may be a protrusion or trench pattern for forming a groove (or trench).

Grooves GR positioned in the inorganic encapsulation area IEA may have an inverse-taper shape. A plurality of grooves GR may be formed. A first groove GR1 may be formed between the first and second tips T1 and T2, a second groove GR2 between the third and fourth tips T3 and T4, a third groove GR3 between the fifth and sixth tips T5 and T6, and a fourth groove GR4 between the seventh and eighth tips T7 and T8. The first groove GR1 may include eave structures formed by the first and second tips T1 and T2, the second groove GR2 may include eave structures formed by the third and fourth tips T3 and T4, the third groove GR3 may include eave structures formed by the fifth and sixth tips T5 and T6, and the fourth groove GR4 may include eave structures formed by the seventh and eighth tips T7 and T8.

Since the light-emitting layers 172 are deposited by evaporation and the common electrode 173 is deposited by sputtering, the light-emitting layers 172 and the common electrode 173 may have poor step coverage and thus may be discontinuously formed in the first through fourth grooves GR1 through GR4. In contrast, the first and second inorganic encapsulation films TFE1 and TFE3, formed by chemical vapor deposition (CVD) or atomic layer deposition (ALD), may have high step coverage and thus may continuously extend through the first through fourth grooves GR1 through GR4. Step coverage refers to the ratio of film coverage on sloped portions relative to flat portions. Each of the first through fourth grooves GR1 through GR4 may include a light-emitting layer 172, a light-emitting layer residual 172_D, the common electrode 173, and a common electrode residual 173_D.

The first dam HDAM1 may include a plurality of sub-dams that include first through fourth sub-dams HDA1 through HDA4. The first dam HDAM1 is illustrated as including only four sub-dams, i.e., the first through fourth sub-dams HDA1 through HDA4, but is not limited thereto. Alternatively, the first dam HDAM1, like the second dam HDAM2, may include three sub-dams.

The first sub-dam HDA1 may be positioned on the first organic film 160 and include the same material as the second organic film 180. The first sub-dam HDA1 may be arranged over the second and third tips T2 and T3. The second sub-dam HDA2 may be arranged on the first sub-dam HDA1 and include the same material as the bank 190. The third and fourth sub-dams HDA3 and HDA4 may be arranged on the second sub-dam HDA2 and include the same material as the spacer, although not limited thereto. The thickness of HDA4 may be greater than that of HDA3, though the aspects of the present disclosure are not limited thereto.

The second dam HDAM2 may include fifth through seventh sub-dams HDA5 through HDA7. The second dam HDAM2, like the first dam HDAM1, may also include four sub-dams.

The fifth sub-dam HDA5 may be positioned on the first organic film 160 and include the same material as the second organic film 180. The fifth sub-dam HDA5 may be positioned on the seventh tip T7. The sixth sub-dam HDA6 may be positioned on the fifth sub-dam HDA5 and include the same material as the bank 190. The seventh sub-dam HDA7 may be positioned on the sixth sub-dam HDA6 and include the same material as the spacer 191, but is not limited thereto.

Since the light-emitting layers 172 and the common electrode 173 are disconnected in each of the first through fourth grooves GR1 through GR4 formed by the first through eighth tips T1 through T8, they may be prevented from becoming pathways for oxygen, moisture, or other penetrants.

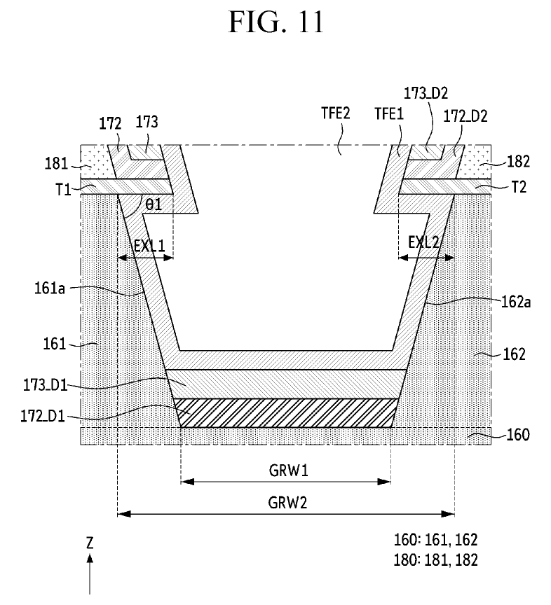

FIG. 11 is a partially enlarged view of region L of FIG. 10. FIG. 11 illustrates the shape before deformation of the first organic film.

Referring to FIG. 11, the first organic film 160 may include a first sub-organic film 161 and a second sub-organic film 162 facing each other. The second organic film 180 may be positioned on the first organic film 160 and may include a third sub-organic film 181 and a fourth sub-organic film 182. The fourth sub-organic film 182 corresponds to the first sub-dam, but will hereinafter be referred to as an organic film for convenience. The first sub-dam may include the same material as the second organic film 180.

The display device according to an aspect may include a first residual 172_D1, a second residual 173_D1, a third residual 172_D2, and a fourth residual 173_D2. To indicate the correlation with a light-emitting element in the display area DA, reference numerals are included in this drawing. However, the light-emitting layer 172 and the common electrode 173 on the first tip T1, illustrated in some enlarged view, may actually be residuals. Since the light-emitting layer 172 and common electrode 173 are disconnected at the first tip T1, the first and second residuals 172_D1 and 173_D1 may be formed. Also, the third and fourth residuals 172_D2 and 173_D2 may be formed from the second tip T2. The third residual 172_D2 may include the same material as the light-emitting layer 172 and the first residual 172_D1, and the fourth residual 173_D2 may include the same material as the common electrode 173 and the second residual 173_D1.

The third sub-organic film 181 may be positioned on the first sub-organic film 161, and the fourth sub-organic film 182 may be positioned on the second sub-organic film 162.

The first tip T1 may be positioned between the first sub-organic film 161 and the third sub-organic film 181. The first tip T1 may be positioned between the first sub-organic film 161 and the second organic film 180. The second tip T2 may be positioned between the second sub-organic film 162 and the fourth sub-organic film 182. The second tip T2 may be positioned between the second sub-organic film 162 and the second organic film 180. The first and second tips T1 and T2 may each include an exposed portion not covered by the first and second organic films 160 and 180. The first and second tips T1 and T2 may be arranged to face each other.

An exposed portion of the first tip T1 not covered by the first sub-organic film 161 and the second organic film 180 may have a first exposure length EXL1. An exposed portion of the second tip T2 not covered by the second sub-organic film 162 and the second organic film 180 may have a second exposure length EXL2. The sum of the first and second exposure lengths EXL1 and EXL2 may be less than a first width GRW1 or a second width GRW2 of the first groove GR1.

In one aspect, the first or second exposure length EXL1 or EXL2 may be within 2 μm. If the first or second exposure length EXL1 or EXL2 exceeds 2 μm, the first inorganic encapsulation film TFE1 covering the first and second tips T1 and T2 may be formed too thin. If the thickness of the first inorganic encapsulation film TFE1 is reduced, its connectivity in the first groove GR1 may be reduced, resulting in a weakened adhesion strength. The first or second exposure length EXL1 or EXL2 need to be positive for the formation of the first, second, and third residuals 172_D1, 172_D2, and 173_D1, should not be too large to ensure good adhesion of the first encapsulation inorganic film TFE1.

The first groove GR1 may have an inverse-taper shape. Accordingly, the first groove GR1 may have the first and second widths GRW1 and GRW2. In one aspect, the first and second widths GRW1 and GRW2 may be 0.1 μm to 8 μm. The first width GRW1 may be smaller than the second width GRW2. The sum of the first and second exposure lengths EXL1 and EXL2 may be smaller than the second width GRW2.

The first inorganic encapsulation film TFE1 may be formed while covering the first and second tips T1 and T2. The first inorganic encapsulation film TFE1 may also cover first and second opposing inclined surfaces 161a and 162a. In one aspect, the lower surface of the first tip T1 and the first opposing inclined surface 161a may form a first angle θ1. The part of the first inorganic encapsulation film TFE1 in contact with the lower surface of the first tip T1 and the part in contact with the first opposing inclined surface 161a may both form the first angle θ1. The first angle θ1 may be 45 degrees or more.

When the first inorganic encapsulation film TFE1 is formed at such an angle, the first inorganic encapsulation film TFE1 may function like a buckle. The first inorganic encapsulation film TFE1 in contact with the lower surface of the first tip T1 may generate a force that pushes away the lower surface of the first tip T1 during detachment of the second protective film PRF2. The first tip T1 is positioned between the first sub-organic film 161 and the second organic film 180 and is fixed by the second organic film 180. Thus, a force with which the first tip T1 pushes away the first encapsulation inorganic film TFE1 may occur as a reaction to the force that pushes away the lower surface of the first tip T1. The first inorganic encapsulation film TFE1 may be fixed to the bottom of the first tip T1 like a buckle, and the reaction force of the first tip T1 may become resistant to the detachment force for the second protective film PRF2. Therefore, the adhesion strength of the first inorganic encapsulation film TFE1 may be strengthened.

The first inorganic encapsulation film TFE1 may be formed to cover at once at least part of the first opposing inclined surface 161a, at least part of the lower surface of the first tip T1, and the lower surface of the first groove GR1. In the display device according to an aspect, in addition to the resistance provided by the first tip T1, the adhesion strength of the first inorganic encapsulation film TFE1 may be further enhanced by ridges and depressions that will be described later. The adhesion strength of the first inorganic encapsulation film TFE1 may be increased not only by contact with the first tip T1 but also by contact with such ridges and depressions.

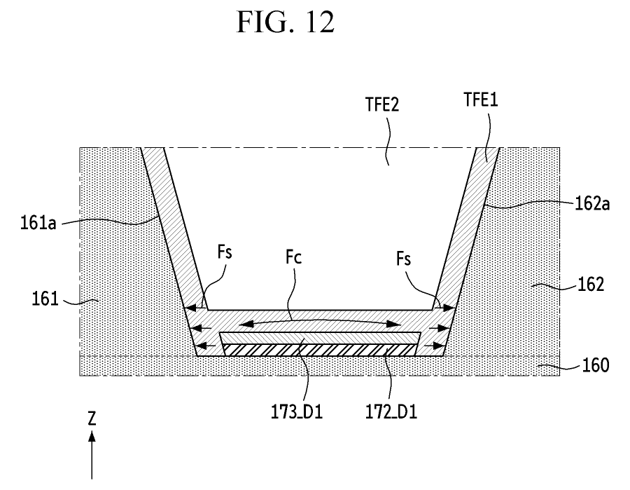

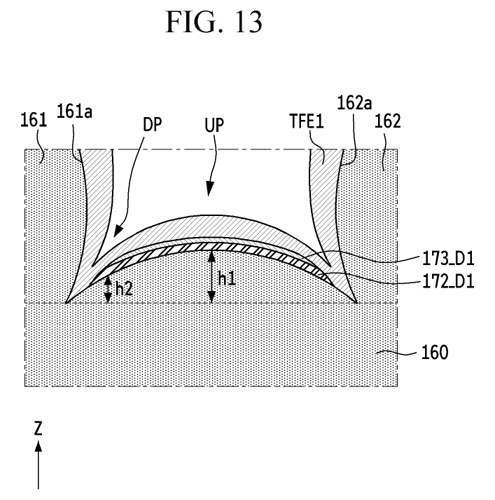

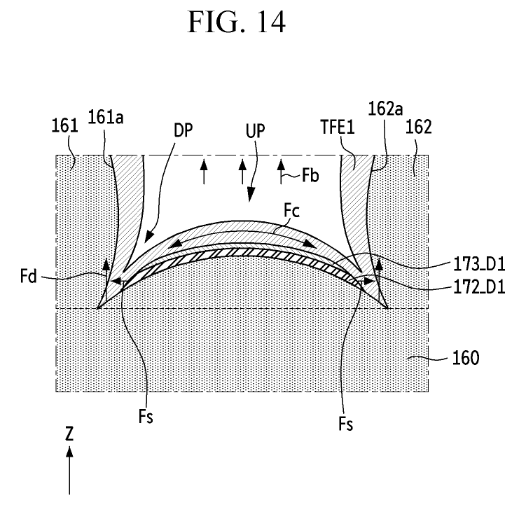

FIG. 12 is a partially enlarged view illustrating a portion of the structure depicted in FIG. 11. FIGS. 13 and 14 are partially enlarged views illustrating shapes after deformation in the structures depicted in FIGS. 11 and 12.

Referring to FIG. 12, the first sub-organic film 161, the second sub-organic film 162, and a first residual 172_Dand a second residual 173_D, positioned between the first and second sub-organic films 161 and 162, may be arranged in the display device according to an aspect of the present disclosure. Thereafter, the first inorganic encapsulation film TFE1 and the organic encapsulation film TFE2 may be deposited on the first and second residuals 172_D and 173_D using a CVD method. The first inorganic encapsulation film TFE1 may be conformally formed with a small thickness along the surface shapes of the first and second residuals 172_D and 173_D.

The first inorganic encapsulation film TFE1, deposited on the first and second residuals 172_D and 173_D, may have a compressive stress, which may be greater than approximately –500 MPa and less than 0 MPa. This compressive stress may act as a force fc that pushes the first inorganic encapsulation film TFE1 and bends the first inorganic encapsulation film TFE1 downward.

If the compressive stress falls outside of the above range, the quality of films formed on the first inorganic encapsulation film TFE1 may deteriorate, degrading electrical characteristics of the display device according to an aspect of the present disclosure, or a dislocation may occur at an interface between the first inorganic encapsulation film TFE1 and other thin films formed thereon due to excessive stress. Also, it may be difficult to form a protrusion UP between the first and second sub-organic films 161 and 162 simply through the deposition of the first inorganic encapsulation film TFE1.

Moreover, when the modulus of the first inorganic encapsulation film TFE1 is smaller than that of a first organic film 160 including the first and second sub-organic films 161 and 162, the first organic film 160 may have a greater rigidity or strength than the first inorganic encapsulation film TFE1, making it difficult to generate a compressive stress, repulsive force, or protrusion through a deposition process alone. Thus, it is necessary to adjust the modulus of the first inorganic encapsulation film TFE1 so that the first inorganic encapsulation film TFE1 may have a greater modulus than the first organic film 160. In this case, a desired compressive stress or protrusion phenomenon may be achieved between the first and second sub-organic films 161 and 162 simply through the deposition of the first inorganic encapsulation film TFE1.

When such compressive stress acts, a repulsive force to push as much as possible in opposite horizontal directions between the inorganic materials may be generated, and due to the force Fc pushing horizontally at both edge portions of the first inorganic encapsulation film TFE1, deposited on the first and second residuals 172_D and 173_D, a repulsive force Fs horizontally pushing the lower parts of opposing inclined surfaces of the first and second sub-organic films 161 and 162 may be generated.

As such, when the repulsive force Fs pushing the lower parts of the opposing inclined surfaces of the first and second sub-organic films 161 and 162 is generated, the adhesion between the first inorganic encapsulation film TFE1 and the first organic film 160 or a component positioned below the first inorganic encapsulation film TFE1 (e.g., an interlayer insulating film) may be enhanced.

In one aspect, the generation of a protrusion may vary depending on the material of a substrate in the display device according to an aspect of the present disclosure. For example, when the substrate includes a rigid material, only the repulsive force may be generated. When the substrate includes a ductile material, a protrusion phenomenon to be described below may occur, and a protrusion and/or a depression may be generated. The following description is based on a case where the substrate is ductile and a protrusion and/or a depression is generated, but the present disclosure is not limited thereto.

Referring to FIG. 13, a counterclockwise torque may occur in the lower part of the first sub-organic film 161, and a clockwise torque may occur in the lower part of the second sub-organic film 162. As a result, a protrusion UP may be formed.

The opposing inclined surfaces (or first and second opposing inclined surfaces 161a and 162a) of the first and second sub-organic films 161 and 162 may include partial curved surfaces, and a protrusion UP having a convex curvature in the thickness direction (e.g., the Z-axis direction) may be formed between the first and second sub-organic films 161 and 162.

Depressions DP may be formed at regions where the lower parts of the first and second opposing inclined surfaces 161a and 162a of the first and second sub-organic films 161 and 162 and the upper surface of the protrusion UP between the first and second sub-organic films 161 and 162 meet.

In one aspect, the depressions DP may be defined by the first and second opposing inclined surfaces 161a and 162a of the first organic film 160 and the upper surface of the protrusion UP. Specifically, the depressions DP may be formed at regions where the lower parts of the first and second opposing inclined surfaces 161a and 162a and both end edges of the upper surface of the protrusion UP meet, and may include first side surfaces defined by the first and second opposing inclined surfaces 161a and 162a and second side surfaces defined by the upper surface of the protrusion UP. The width between the first side surfaces and the second side surfaces may decrease in a direction from the tops toward the bottoms of the depressions DP, and the first side surfaces and the second side surfaces may overlap at the ends of the depressions DP.

Also, the ends of the depressions DP may be aligned with the upper surface of the first organic film 160 that is positioned outside the first and second sub-organic films 161 and 162, but the present disclosure is not limited thereto.

The upper surface of the protrusion UP may be positioned higher than the upper surface of the first organic film 160 that is located outside the first and second sub-organic films 161 and 162. Specifically, a central portion of the upper surface of the protrusion UP may be located at a first height h1 above the upper surface of the first organic film 160, and portions adjacent to the depressions DP may be located at a second height h2. The first height h1 may be greater than the second height h2 and may range from approximately 31.5 μm to 52 μm, but is not limited thereto.

The first and second residuals 172_D and 173_D, the first inorganic encapsulation film TFE1, the organic encapsulation film TFE2, and the second inorganic encapsulation film TFE3 may be sequentially arranged on the first and second sub-organic films 161 and 162, the protrusion UP, and the depressions DP.

The first and second residuals 172_D and 173_D may be arranged along the upper surfaces of the first organic film 160 and the protrusion UP. The first and second residuals 172_D and 173_D may be in direct contact with the upper surface of the protrusion UP, and the first and second residuals 172_D and 173_D on the protrusion UP may include a convex curvature in the thickness direction.

The first inorganic encapsulation film TFE1 arranged on the protrusion UP may have an upper surface in contact with the second inorganic encapsulation film TFE3 and a lower surface in contact with the first and second residuals 172_D and 173_D. The curvature of the upper surface of the first inorganic encapsulation film TFE1 may be greater than that of the lower surface of the first inorganic encapsulation film TFE1, and the radius of curvature of the upper surface of the first inorganic encapsulation film TFE1 may be smaller than that of the lower surface of the first inorganic encapsulation film TFE1.

The first inorganic encapsulation film TFE1 may be positioned on the first and second residuals 172_D and 173_D. Specifically, the first inorganic encapsulation film TFE1 may be positioned on the first and second opposing inclined surfaces 161a and 162a and the upper surface of the first organic film 160.

In one aspect, the first and second residuals 172_D and 173_D may not be positioned on at least some parts of the first organic film 160 and the protrusion UP. In this case, the first inorganic encapsulation film TFE1 may directly contact the protrusion UP or the first organic film 160.

The organic encapsulation film TFE2, positioned on the first inorganic encapsulation film TFE1, may form a protrusion toward the depressions DP in the gap between the first and second sub-organic films 161 and 162.

A case in which a bending stress is applied will hereinafter be described with reference to FIG. 14. Referring to FIG. 14, when a bending stress acts, a force to peel the first inorganic encapsulation film TFE1 and the organic encapsulation film TFE2 from the first organic film 160 and the protrusion UP may occur. Such a delamination force Fb is typically oriented vertically.

Due to the compressive stress between the inorganic materials, a force Fc pushing horizontally may be generated in the first inorganic encapsulation film TFE1 on the protrusion UP, and as a result, a repulsive force Fs horizontally pushing the lower region between the first and second sub-organic films 161 and 162 may occur. For a compressive force to act, the spacing between the first and second organic films 161 and 162 may be sufficiently narrow. For example, the spacing between the first and second organic films 161 and 162 may be approximately 0.1 μm to 8 μm as the groove width.

Thus, due to the repulsive force Fs, a shear force may be generated at the lower parts of the first and second opposing inclined surfaces 161a and 162a of the first and second sub-organic films 161 and 162, thereby weakening the delamination force Fb in the vertical direction. That is, the first inorganic encapsulation film TFE1 in the depressions DP may push the first and second opposing inclined surfaces 161a and 162a, and the adhesion between the first and second sub-organic films 161 and 162 and the first inorganic encapsulation film TFE1 may be enhanced. The shear force may act as a resistance to the delamination force Fb, thus improving the adhesion of the first inorganic encapsulation film TFE1 to the first organic film 160.

In one aspect, outer inclined surfaces of the first inorganic encapsulation film TFE1 on the first and second opposing inclined surfaces 161a and 162a of the first and second sub-organic films 161 and 162 may cover the first and second residuals 172_D and 173_D and the first inorganic encapsulation film TFE1 in the depressions DP, thereby serving as a direct resistance to the delamination force Fb.

Since the first and second residuals 172_D and 173_D, the first inorganic encapsulation film TFE1, and the second inorganic encapsulation film TFE3, arranged in the depressions DP, decrease in width toward the bottoms of the depressions DP, the adhesion between the first and second residuals 172_D and 173_D, the first inorganic encapsulation film TFE1, and the second inorganic encapsulation film TFE3 may be enhanced, thus suppressing or preventing delamination of the encapsulation layer ENC from the depression DP.

As a result, the resistance to the vertically acting delamination force Fb may be increased, thereby weakening the delamination force Fb and enhancing the adhesion strength of the first inorganic encapsulation film TFE1. Specifically, the adhesion between the first inorganic encapsulation film TFE1 and the first and second residuals 172_D and 173_D, as well as between the first inorganic encapsulation film TFE1 and the first organic film 160, may be enhanced.

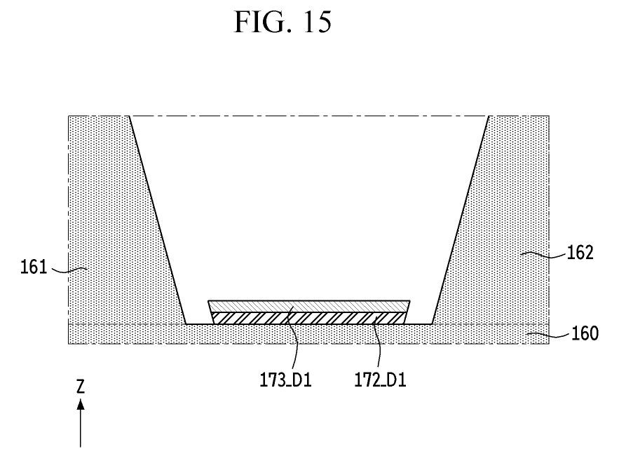

FIGS. 15 through 17 are cross-sectional views illustrating steps in a process of forming the display device according to an aspect of the present disclosure.

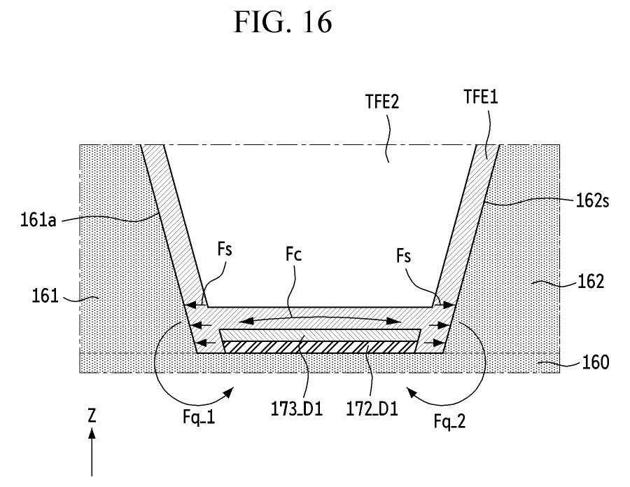

As one step, referring to FIGS. 15 and 16, the first and second sub-organic films 161 and 162, adjacent to each other, may be protruding portions of the first organic film 160 and may be arranged with a gap therebetween. Since there is no external force in the lower region between the first and second sub-organic films 161 and 162, the upper surface of the first organic film 160 may remain flat between the first and second sub-organic films 161 and 162.

The spacing between the first and second sub-organic films 161 and 162 may be 0.1 μm to 10 μm as the groove width. Specifically, the spacing between the first and second sub-organic films 161 and 162 may be about 0.1 μm to 8 μm. If the spacing between the first and second sub-organic films 161 and 162 is outside this range, a horizontal force caused by compressive stress between the stacked inorganic materials may not occur. Accordingly, no external force may act on the lower region between the first and second sub-organic films 161 and 162, and the upper surface of the first organic film 160 may remain flat between the first and second sub-organic films 161 and 162. However, even in this case, some repulsive force may still act, resulting in relatively high adhesion of the first inorganic encapsulation film TFE1.

In one aspect, after forming the first and second residuals 172_D and 173_D on the upper surface of the first organic film 160, between the first and second sub-organic films 161 and 162, the first inorganic encapsulation film TFE1 may be deposited on the first and second residuals 172_D and 173_D using a CVD method. The first inorganic encapsulation film TFE1 may be conformally formed with a small thickness along the surface shapes of the first and second residuals 172_D and 173_D.

The first inorganic encapsulation film TFE1, deposited on the first and second residuals 172_D and 173_D, may have compressive stress, for example, compressive stress in a range of approximately –500 MPa to 0 MPa. This compressive stress may act as a force Fc pushing the first inorganic encapsulation film TFE1 and bending it downward.

When such compressive stress acts, a force pushing outward in opposite horizontal directions between the inorganic materials may occur, and due to the horizontal pushing force Fc from both edges of the first inorganic encapsulation film TFE1 deposited on the first and second residuals 172_D and 173_D, a repulsive force Fs horizontally pushing the lower parts of the first and second opposing inclined surfaces 161a and 162a of the first and second sub-organic films 161 and 162 may be generated.

As such, when the repulsive force Fs acts on the lower parts of the first and second opposing inclined surfaces 161a and 162a of the first and second sub-organic films 161 and 162, a counterclockwise torque Fq_1 may be generated in the lower part of the first sub-organic film 161, and a clockwise torque Fq_2 may be generated in the lower part of the second sub-organic film 162.

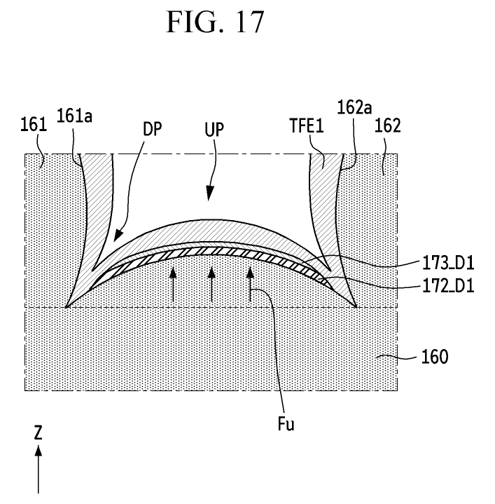

As a subsequent step, referring to FIG. 17, the torques Fq_1 and Fq_2, generated in the lower parts of the first and second sub-organic films 161 and 162, may act on the central portion of the upper surface of the first organic film positioned 160 between the first and second sub-organic films 161 and 162, resulting in a force Fu that causes the central portion of the upper surface of the first organic film positioned 160 to bulge in the thickness direction. Accordingly, a protrusion UP may be formed.

The protrusion UP, depressions DP, and shear force formed in this manner may contribute to enhancing the adhesion between the first inorganic encapsulation film TFE1 and the first and second residuals 172_D and 173_D, as well as between the first and second inorganic encapsulation films TFE1 and TFE2, as described above.

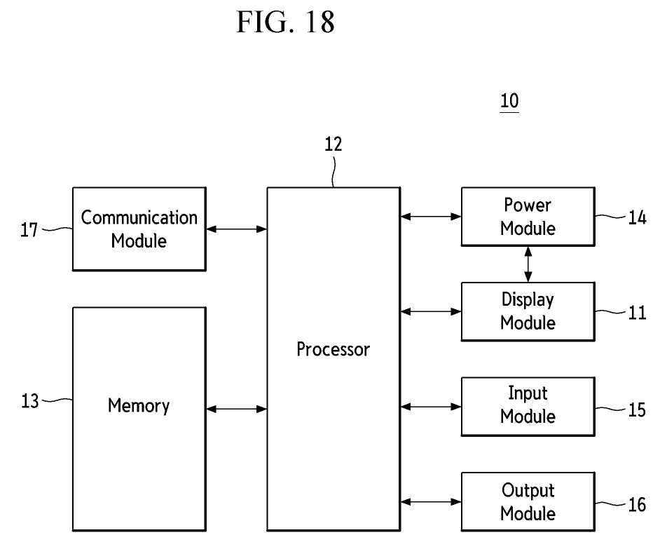

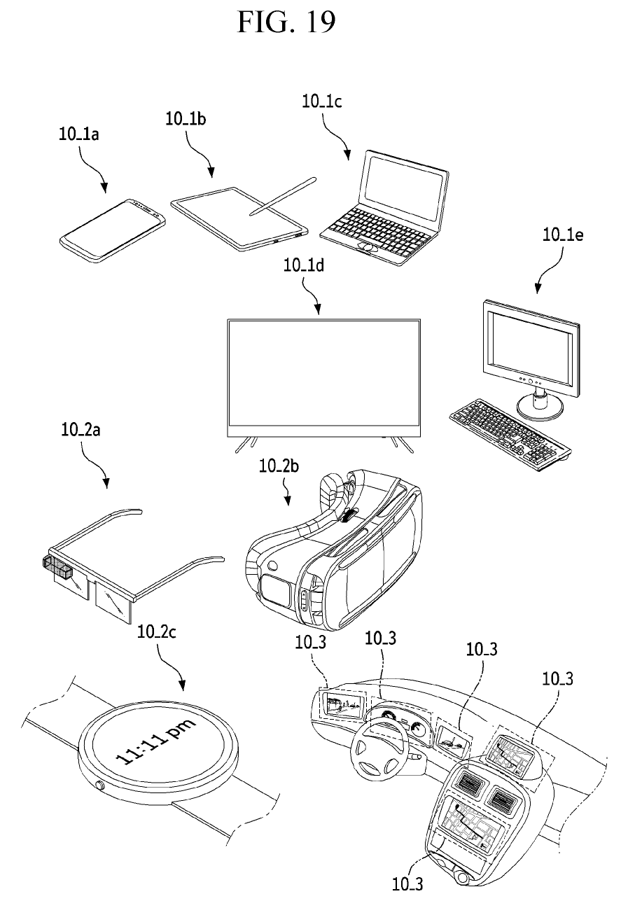

FIG. 18 is a block diagram of an electronic device according to an aspect of the present disclosure, and FIG. 19 presents a set of schematic views of electronic devices according to various aspects of the present disclosure.

Referring to FIG. 18, an electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data and information required for operation of the processor 12 or display module 11. When the processor 12 executes an application stored in the memory 13, video data signals and/or input control signals may be delivered to the display module 11, and the display module 11 may process the received signals and output image information via a display screen.

The power module 14 may include a power supply module, such as a power adapter or battery device. The power module 14 may include a power conversion module. The power conversion module may convert the power supplied by the power supply module and may thereby generate power required for the operation of the electronic device 10.

At least one of the components of the electronic device 10 described above may be included in the display device according to any one of the aforementioned aspects of the present disclosure. Also, among the individual modules functionally grouped in a single module, some may be included in the display device according to any one of the aforementioned aspects of the present disclosure and others may be provided separately. For example, the display device according to any one of the aforementioned aspects of the present disclosure may include the display module 11, while the processor 12, the memory 13, and the power module 14 may be provided as other devices than the display device according to any one of the aforementioned aspects of the present disclosure, within the electronic device 10.

Referring to FIG. 19, various electronic devices 10 to which the display device according to any one of the aforementioned aspects of the present disclosure is applicable may include image display electronic devices such as a smartphone 10_1a, a tablet PC 10_1b, a laptop 10_1c, a TV 10_1d, or a desktop monitor 10_1e. Further, the various electronic devices 10 may include wearable electronic devices including a display module, such as smart glasses 10_2a, a head-mounted display 10_2b, or a smartwatch 10_2c, or vehicle electronic devices 10_3 including a display module, such as an instrument cluster, a center fascia, a center information display (CID) arranged on the dashboard, or a room mirror display.

The advantages and features of the aspects disclosed herein, and methods of achieving them, will become apparent upon reference to the aspects described in detail with accompanying drawings. However, the aspects according to the present disclosure are not limited to the aspects disclosed herein, but will take many different forms, and these aspects are provided merely to make the disclosure complete and to fully inform one of ordinary skill in the art to which the present disclosure belongs, and the scope of the present disclosure is defined by the scope of the claims.

What is claimed is:

1. A display device comprising:
an inorganic encapsulation area surrounding a through-hole;
a wiring area surrounding the inorganic encapsulation area; and
a display area surrounding the wiring area,
wherein the inorganic encapsulation area includes:
a first organic film including a first sub-organic film having a first inclined surface and a second sub-organic film having a second inclined surface, wherein the second inclined surface faces the first inclined surface;
a first groove between the first sub-organic film and the second sub-organic film; and
a protrusion comprising at least a portion of the first organic film, wherein the protrusion is between the first sub-organic film and the second sub-organic film.

2. The display device of claim 1, wherein the inorganic encapsulation area further includes: a second organic film on the first organic film; and a plurality of tips, each tip of the plurality of tips including an exposed portion defined by the first organic film and the second organic film.

3. The display device of claim 2, wherein the plurality of tips includes a first tip positioned between the first sub-organic film and the second organic film.

4. The display device of claim 3, wherein the display area includes:
a first organic film including a same material as the first organic film in the inorganic encapsulation area;
a second connection electrode on the first organic film, the second connection electrode including a same material as the first tip;
a second organic film on the second connection electrode, the second organic film including a same material as the second organic film in the inorganic encapsulation area;
a plurality of pixel electrodes on the second organic film;
a common electrode on the plurality of pixel electrodes; and
light-emitting layers positioned between the plurality of pixel electrodes and the common electrode.

5. The display device of claim 3, wherein the plurality of tips further includes a second tip facing the first tip and positioned between the second sub-organic film and the second organic film.

6. The display device of claim 5, wherein
a portion of the first tip, exposed by the first sub-organic film and the second organic film, has a first exposure length,
a portion of the second tip, exposed by the second sub-organic film and the second organic film, has a second exposure length, and
a sum of the first exposure length and the second exposure length is less than a width of the first groove.

7. The display device of claim 6, wherein
the first groove has an inverse-taper shape,
the first groove has a first width and a second width,
the second width is greater than the first width, and
the sum of the first exposure length and the second exposure length is less than the second width.

8. The display device of claim 3, wherein
a lower surface of the first tip and the first inclined surface of the first sub-organic film form a first angle, and
the first angle is equal to or greater than 45 degrees and less than 90 degrees.

9. The display device of claim 3, wherein
a portion of the first tip, exposed by the first sub-organic film and the second organic film, has a first exposure length, and
the first exposure length is greater than 0 μm and less than 2 μm.

10. The display device of claim 1, wherein
the first groove has an inverse-taper shape,
the first groove has a first width and a second width,
the second width is greater than the first width, and
the second width is greater than 0 μm and equal to or less than 8 μm.

11. The display device of claim 1, wherein the inorganic encapsulation area further includes a depression between the first inclined surface and the protrusion.

12. The display device of claim 1, wherein
the display area includes: a plurality of pixel electrodes; a common electrode positioned on the plurality of pixel electrodes; and light-emitting layers positioned between the plurality of pixel electrodes and the common electrode, and
the inorganic encapsulation area further includes a first residual in the first groove, the first residual including a same material as the light-emitting layers.

13. The display device of claim 12, wherein the inorganic encapsulation area further includes a second residual on the first residual, the second residual including a same material as the common electrode.

14. The display device of claim 13, wherein the inorganic encapsulation area further includes a first inorganic encapsulation film that covers at least a portion of the first inclined surface, at least a portion of the second inclined surface, and the second residual.

15. The display device of claim 11, wherein the inorganic encapsulation area further includes a first inorganic encapsulation film that simultaneously covers at least a portion of the first inclined surface, at least a portion of the depression, and at least a portion of the protrusion.

16. An electronic device comprising:
a processor configured to provide an image signal;
a display module configured to receive the image signal from the processor and display an image; and
a power module configured to supply power to the display module,
wherein:
the display module includes: an inorganic encapsulation area surrounding a through-hole; a wiring area surrounding the inorganic encapsulation area; and a display area surrounding the wiring area, and
the inorganic encapsulation area includes: a first organic film including a first sub-organic film having a first inclined surface and a second sub-organic film having a second inclined surface, wherein the second inclined surface faces the first inclined surface; a first groove between the first sub-organic film and the second sub-organic film; and a protrusion comprising at least a portion of the first organic film, wherein the protrusion is between the first sub-organic film and the second sub-organic film.

17. The electronic device of claim 16, wherein:
the inorganic encapsulation area further includes: a second organic film on the first organic film; and a plurality of tips, each tip of the plurality of tips including an exposed portion defined by the first organic film and the second organic film, and
the plurality of tips includes a first tip positioned between the first sub-organic film and the second organic film.

18. The electronic device of claim 16, wherein the inorganic encapsulation area further includes a depression between the first inclined surface and the protrusion.

19. The electronic device of claim 16, wherein
the display area includes: a plurality of pixel electrodes; a common electrode positioned on the plurality of pixel electrodes; and light-emitting layers positioned between the plurality of pixel electrodes and the common electrode, and
the inorganic encapsulation area includes: a first residual in the first groove, the first residual including a same material as the light-emitting layers; and a second residual on the first residual, the second residual including a same material as the common electrode.

20. The electronic device of claim 18, wherein the inorganic encapsulation area further includes a first inorganic encapsulation film that simultaneously covers at least a portion of the first inclined surface, at least a portion of the depression, and at least a portion of the protrusion.
